(19) United States
(12) Patent Application Publication
(10) Pub. No.: US 2013/0039006 A1
(43) Pub. Date: Feb. 14, 2013

(54) SERVER RACK ASSEMBLY

(71) Applicants: HAN-YU LI, Tu-Cheng (TW); YUN-QUAN TANG, Shenzhen City (CN); DA-HONG LONG, Shenzhen City (CN); GUANG-DONG HE, Shenzhen City (CN)

(72) Inventors: HAN-YU LI, Tu-Cheng (TW); YUN-QUAN TANG, Shenzhen City (CN); DA-HONG LONG, Shenzhen City (CN); GUANG-DONG HE, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/486,130

(22) Filed: Jun. 1, 2012

(30) Foreign Application Priority Data
Aug. 9, 2011 (CN) 201110227160.6

(51) Int. Cl. H05K 7/20; H05K 7/18

(52) U.S. Cl. 361/679.48; 361/679.02

(57) ABSTRACT

A server rack assembly receives a plurality of servers. The server rack assembly includes a server rack, a bus-bar, and a power supply. The server rack includes a stand column. The server rack defines a plurality of server spaces for receiving the plurality of servers. A bus-bar is mounted to the server rack and includes a plurality of connectors aligned in a first direction substantially parallel to the stand column. The bus-bar is adapted to electronically plug to the plurality of servers. The power supply device is electronically connected to a middle portion of the bus-bar. The power supply device is adapted to output direct current to the bus-bar.

### CROSS-REFERENCE TO RELATED APPLICATIONS

This application claims all benefits accruing under 35 U.S.C. §119 from China Patent Application No. 201110227160.6, filed on Aug. 9, 2011, in the China Intellectual Property Office, the contents of which are hereby incorporated by reference. Relevant subject matter is disclosed in co-pending U.S. Patent Applications entitled “SERVER RACK ASSEMBLY”, Attorney Docket Number US40572, U.S. application No. ______, filed on ______; co-pending U.S. Patent Applications entitled “SERVER RACK ASSEMBLY”, Attorney Docket Number US40624, U.S. application No. ______, filed on ______; and co-pending U.S. Patent Applications entitled “SERVER RACK ASSEMBLY”, Attorney Docket Number US40569, U.S. application No. ______, filed on ______.

### BACKGROUND

1. Technical Field

The present disclosure relates for rack of electronic devices, more particularly to a server rack assembly.

2. Description of Related Art

Blade and rack-mounted servers are popular form factors for data center servers. In order to achieve high performance, many rack-mounted servers are clustered in an enclosure. A server rack assembly may include a server rack and a number of servers received in the server rack. A height of each of servers may be 1U (1U=1.75 inch), and a height of the server rack may be 37U or 42U, for example. Each of the servers is connected to a power supply via a number of cables. Thus, a number of power supplies and a number of cables are needed in the server rack. It can be confusing during maintenance because many different power supplies and cables. Therefore, an improved server rack assembly may be needed within the art.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an assembled view of a server rack assembly in accordance with a first embodiment.

FIG. 2 is similar to FIG. 1, but shown with a plurality of servers and two switches mounted in the server rack assembly.

FIG. 3 is a rear view of the server rack assembly in FIG. 2.

FIG. 4 is a rear view of a server rack assembly in accordance with a second embodiment.

FIG. 5 is a rear view of a server rack assembly in accordance with a third embodiment.

FIG. 6 is a rear view of a server rack assembly in accordance with a fourth embodiment.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

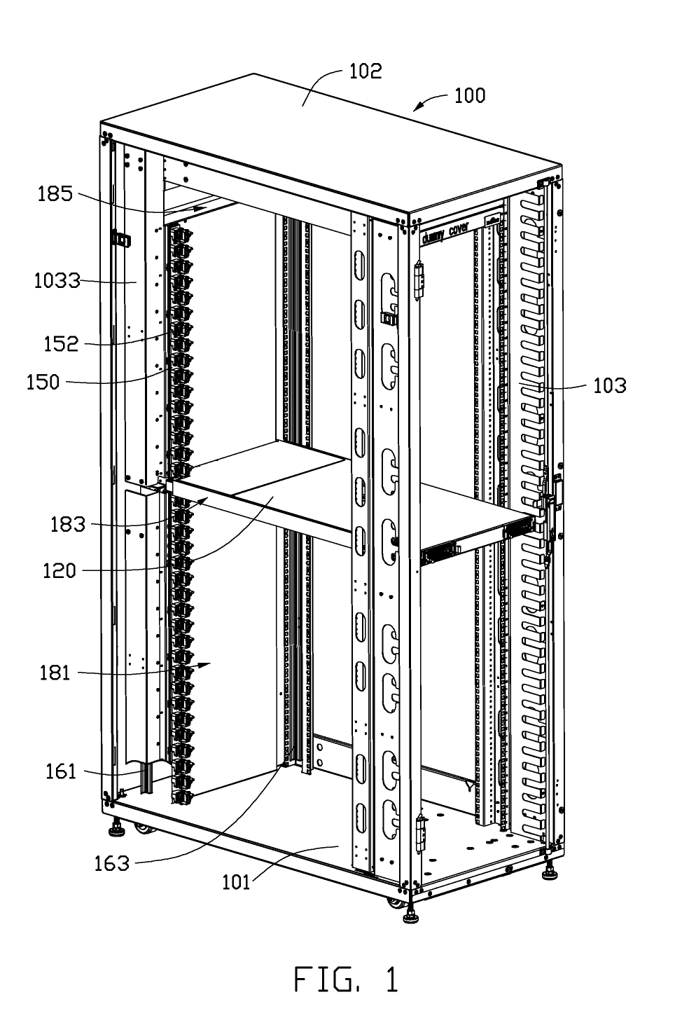

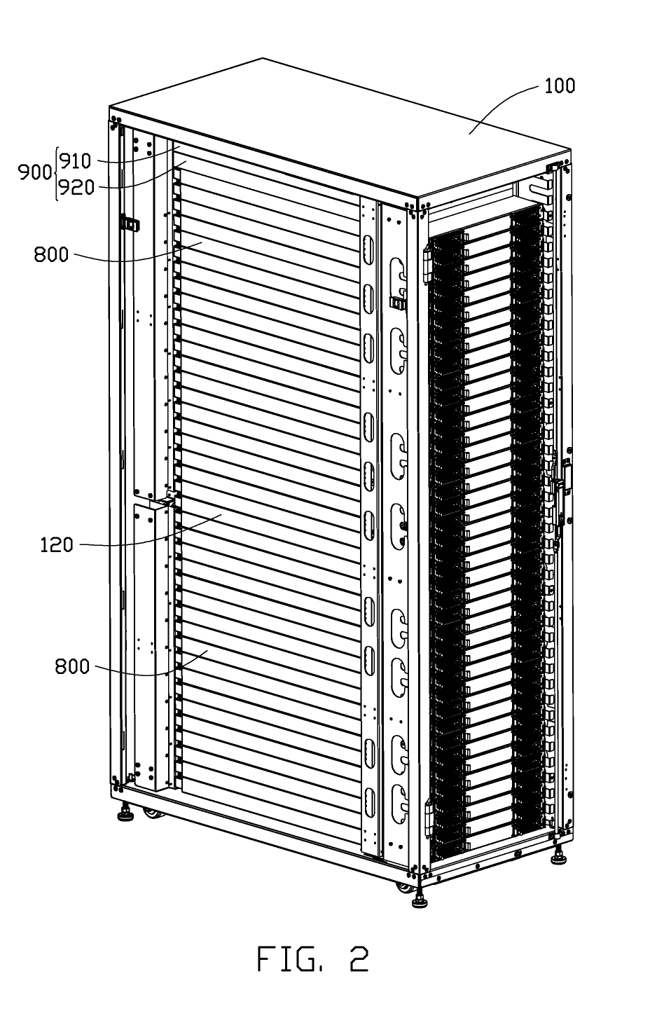

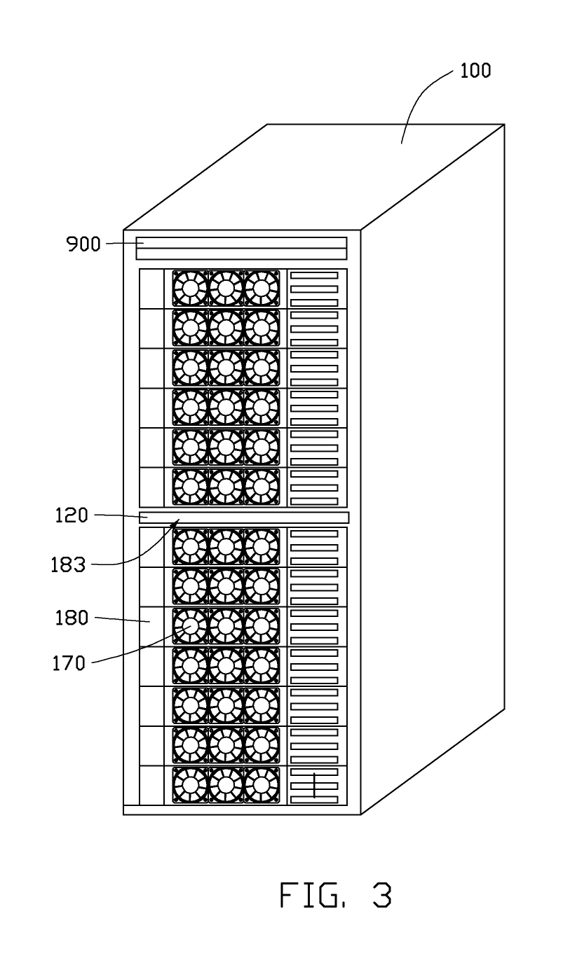

FIGS. 1 to 3 show a server rack assembly in accordance with a first embodiment including a server rack 100 and a plurality of servers 800 detachably mounted to the server rack 100. The server rack 100 includes a bottom wall 101, a top wall 102, a bracket 103, a power supply device 120, a bus-bar 150 mounted on the bracket 103, a plurality of fan modules 170, and a plurality of control panels 180. The bracket 103 includes a plurality of stand columns 1033 substantially perpendicular to the bottom wall 101 and the top wall 102. In the first embodiment, the server rack 100 is 42U so that the server rack 100 may receive at most 42 1U components, which may include 39 1U servers, two 1U switches, and one 1U power supply.

The power supply device 120 receives alternating current and converts the alternating current into direct current used by the plurality of servers 800. The bus-bar 150 is electrically connected to the power supply device 120. The bus-bar 150 is mounted on the stand column 1033. The bus-bar 150 includes a plurality of connectors 152. The plurality of connectors 152 are aligned in a first direction substantially parallel to the stand column 1033. Each of the plurality of connectors 152 can receive each of the plurality of servers 800. Each of the plurality of fan modules 170 is electrically connected to the bus-bar 150. Each of the plurality of fan modules 170 includes one or more fans. The control panel 180 is connected between the plurality of fan modules 170 and the plurality of servers 800.

A plurality of server spaces 181 is defined in the server rack 100 along a vertical direction for receiving the plurality of servers 800. A power supply space 120 is defined in the server rack 100 for receiving the power supply device 120. Two switch spaces 185 are defined for receiving two switches 900. Each of the plurality of server spaces 185 can receive the plurality of servers 800 along a second direction substantially perpendicular to the stand column 1033. Each of the plurality of servers 800 is approximately 1U high. The power supply space 183 can receive the power supply device 120 along the second direction. Each of the server spaces 181, the power supply space 183, and each of the switch spaces 185 have approximately the same height.

Each of the connectors 152 is located in each of the server spaces 181. The power supply space 183 is located at a middle portion of the plurality of server spaces 181. In another embodiment, if the power supply device 120 is located at another location, the power supply device 120 may connect to substantially the middle portion of the bus-bar 150. A height of each of the plurality of fan modules 170 is approximately the triple height of each of the plurality of server spaces 181.

The two switches 900 include a first switch 910 and a second switch 920. The server rack 100 may further include a plurality of first cables 161 and a plurality of second cables 163 for connecting the first switch 910 to the plurality of servers 800. The plurality of first cables 161 and the plurality of second cables 163 are located at two separate stand columns 1033 on opposite sides of the plurality of server spaces 181. The first switch 910 and the second switch 920 can connect the plurality of servers 800 to an internal network, such as intranet, or an external network, such as the internet.

Each of the plurality of server spaces 181 and the power supply space 183 have approximately the same height. The number of the server spaces 181 may be 39. The power supply space 183 may divide the plurality of server spaces 181 into 18 server spaces and 21 server spaces. The server spaces 181 located in both sides of the power supply space 183 are arranged in series. Each of the control panel 180 is connected to each of the plurality of fan modules 170. A height of each of the control panel 180 is approximately equal to the height of each of the plurality of fan modules 170.

In use, the power supply device 120 is moved to the power supply space 183 and is directly plugged into the bus-bar 150 without wires or cables. The two switches 900 are moved into the two switch spaces 185. The plurality of servers 800 are moved into the plurality of server spaces 181 with each of the plurality of servers 800 directly plugged into each of the plurality of connectors 152. The power supply device 170 can supply direct current to the plurality of servers 800 and the plurality of fan modules 170.

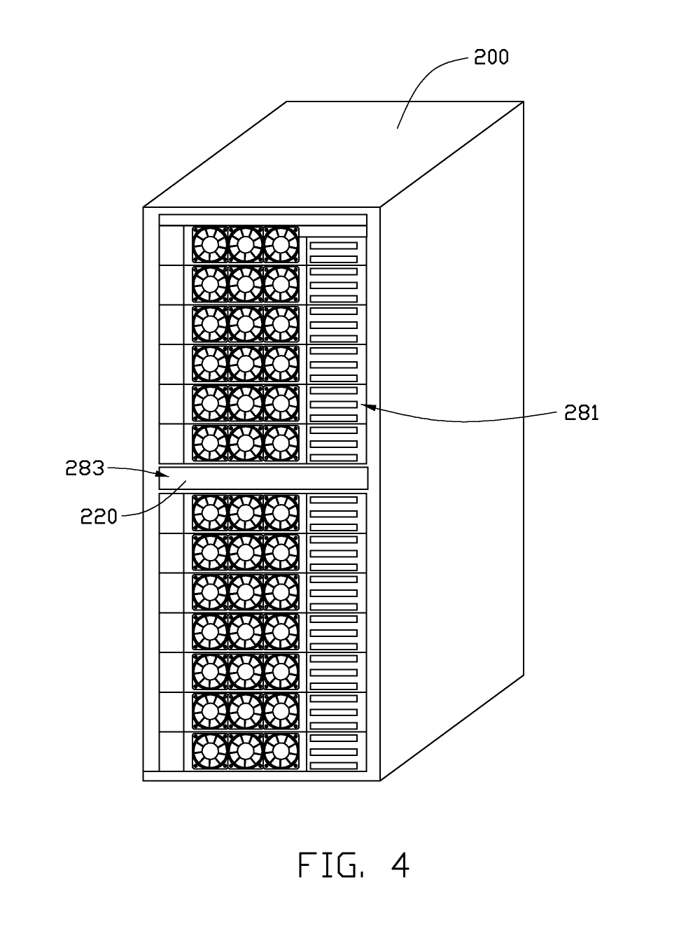

FIG. 4 shows a server rack 200 in a second embodiment The server rack 200 may have a plurality of server spaces 281 with a different arrangement than in the first embodiment. In the second embodiment, a power supply space 283 may be about twice the height of each of the plurality of server spaces 281. A number of the plurality of server space 281 may be 38. The power supply space 283 can divide the plurality of server spaces 281 into 17 server spaces and 21 server spaces.

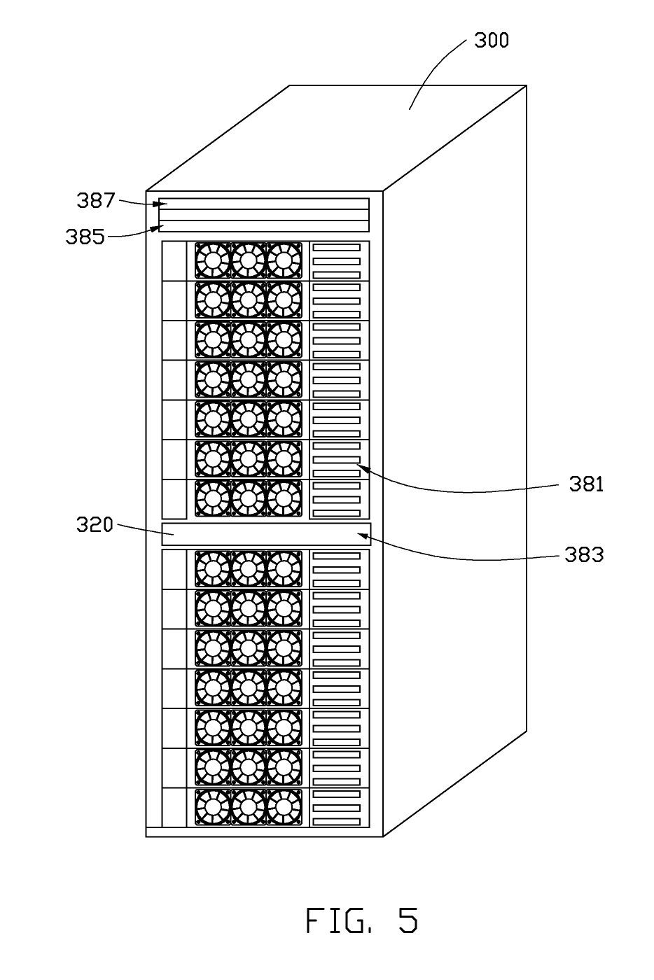

FIG. 5 shows a server rack 300 in a third embodiment. The server rack 300 may have a plurality of server spaces 381 with a different arrangement than in the first embodiment. In the third embodiment, the server rack 300 is 47U. A power supply space 383 may receive a power supply space 320. The power supply space 383 may be about twice the height of each of the plurality of server spaces 381. A number of the plurality of server spaces 381 may be 42. The power supply space 383 can divide the plurality of server spaces 381 into two 21 server spaces. The server rack 300 may define the plurality of server spaces 381, the power supply space 383, two switches spaces 385, and a spare space 387. The spare space 387 can temporarily store one of the plurality of servers 800.

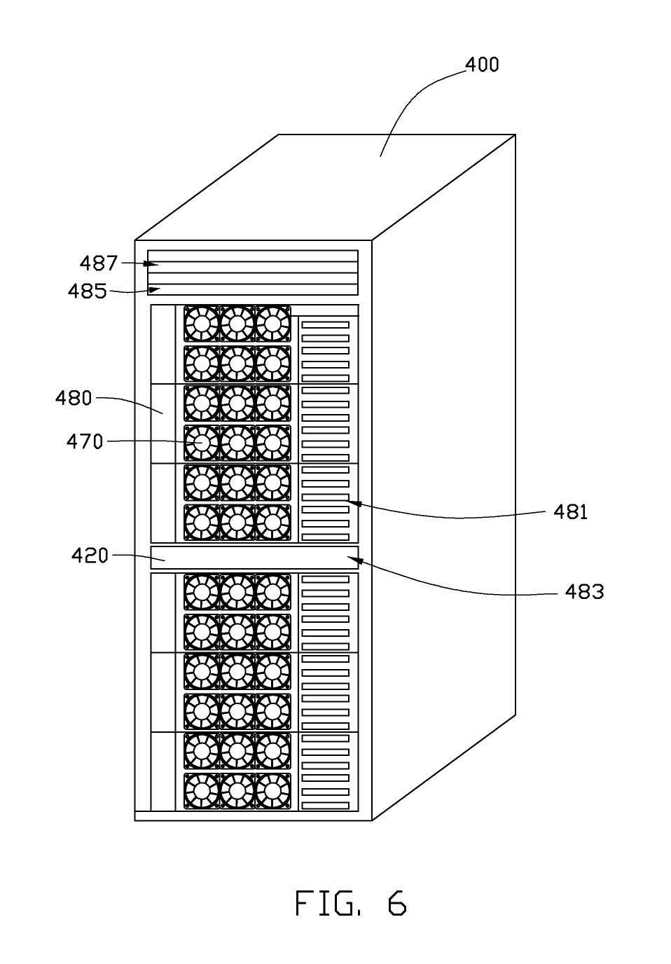

FIG. 6 shows a server rack 400 in a fourth embodiment. The server rack 400 may have a plurality of server spaces 481 with a different arrangement than in the first embodiment. In the fourth embodiment, a power supply space 483 may receive a power supply space 420. The power supply space 483 may be about twice the height of each of the plurality of server spaces 481. A number of the plurality of server spaces 481 may be 36. The power supply space 483 can divide the plurality of server spaces 481 into two 18 server spaces. The server rack 400 may define the plurality of server spaces 481, the power supply space 483, two switches spaces 485, and two spare spaces 487. The spare space 487 can temporarily store one of the plurality of servers 800. The server rack 400 includes a plurality of control panels 480 for connecting a plurality of fan modules 470. Each of the control panels 480 is connected to two adjacent fan modules 470. Each of the control panels 480 is about twice the height of each of fan modules 470, and is six times the height of each of plurality of server spaces 481.

In one embodiment, the power supply device may provide power for all of the connected servers 800. The bus-bar may reduce cables in the server rack 100. The fan modules can dissipate heat for all connected servers 800 in the server rack 100.

It is to be understood, however, that even though numerous characteristics and advantages have been set forth in the foregoing description of embodiments, together with details of the structures and functions of the embodiments, the disclosure is illustrative only and changes may be made in detail, especially in matters of shape, size, and arrangement of parts within the principles of the disclosure to the full extent indicated by the broad general meaning of the terms in which the appended claims are expressed.

What is claimed is:

1. A server rack assembly for receiving a plurality of servers, the server rack assembly comprising:
a server rack comprising a stand column and defining a plurality of server spaces for receiving the plurality of servers;
a bus-bar mounted in the server rack and comprising a plurality of connectors aligned in a first direction substantially parallel to the stand column; and
a power supply device mounted in the server rack and electronically connected to substantially a middle portion of the bus-bar; wherein the bus-bar is adapted to electronically plug to the plurality of servers, and the power supply device is adapted to output direct current to the bus-bar.

2. The server rack assembly of claim 1, wherein the server rack further defines a power supply space for receiving the power supply device, and the power supply space is located at a middle portion of the plurality of server spaces.

3. The server rack assembly of claim 2, wherein the power supply device is plugged to the bus-bar directly as the power supply device moves into the power supply space.

4. The server rack assembly of claim 3, wherein a number of the plurality of server spaces is 42, and the plurality of server spaces are divided by the power supply space into 21 server spaces and 21 server spaces.

5. The server rack assembly of claim 1, wherein a number of the plurality of connectors is not less than a number of the plurality of server spaces.

6. The server rack assembly of claim 1, further comprising a plurality of fan modules for dissipating heat from the plurality of servers, and a height of each of the plurality of fan modules is approximately triple the height of each of the plurality of server spaces.

7. The server rack assembly of claim 6, wherein each of the plurality of fan modules is connected to the bus-bar for receiving power from the power supply device.

8. The server rack assembly of claim 6, further comprising a plurality of control panels, each of the plurality of control panels is connected to two of the plurality of fan modules, and each of the plurality of control panels is approximately equal to a height of each of the plurality of fan modules.

9. The server rack assembly of claim 1, wherein each of the plurality of server spaces is approximately 1U in height.

10. The server rack assembly of claim 1, wherein the server rack further defines a switch space located on one side of the plurality of server spaces for receiving a switch, and each of the plurality of server spaces and the switch space have approximately the same height.

11. A server rack assembly for receiving a plurality of servers, the server rack assembly comprising:
a server rack comprising a stand column and defining a plurality of server spaces for receiving the plurality of servers;
a bus-bar mounted to the server rack and comprising a plurality of connectors aligned in a first direction substantially parallel to the stand column, wherein the bus-bar is adapted to electronically plug to the plurality of servers when the plurality of servers slides into the plurality of servers; and
a power supply device pluggable to a middle portion of the bus-bar along a second direction substantially perpendicular to the stand column.

12. The server rack assembly of claim 11, wherein the power supply device is adapted to output direct current to the bus-bar.

13. The server rack assembly of claim 11, wherein the server rack further defines a power supply space for receiving the power supply device, and the power supply space is located at a middle portion of the plurality of server spaces.

14. The server rack assembly of claim 13, wherein a number of the plurality of server spaces is 42, and the plurality of server spaces are divided by the power supply space into 21 server spaces and 21 server spaces.

15. The server rack assembly of claim 11, wherein a number of the plurality of connectors is not less than a number of the plurality of server spaces.

16. The server rack assembly of claim 11, further comprising a plurality of fan modules for dissipating heat from the plurality of servers, and a height of each of the plurality of fan modules is approximately triple the height of each of the plurality of server spaces.

17. The server rack assembly of claim 16, wherein each of the plurality of fan modules is connected to the bus-bar for receiving power from the power supply device.

18. The server rack assembly of claim 16, further comprising a plurality of control panels, each of the plurality of control panels is connected to two of the plurality of fan modules, and each of the plurality of control panels is approximately equal to a height of each of the plurality of fan modules.

19. The server rack assembly of claim 11, wherein each of the plurality of server spaces is approximately 1U in height.

20. The server rack assembly of claim 11, wherein the server rack further defines a switch space located on one side of the plurality of server spaces for receiving a switch, and each of the plurality of server spaces and the switch space have approximately the same height.
